(19) United States
(12) Patent Application Publication
(10) Pub. No.: US 2026/0314337 A1
(43) Pub. Date: Oct. 8, 2026

(54) SEMICONDUCTOR DEVICE AND METHOD OF MONITORING PROCESS DEFECTS OF SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 19/294,290

(22) Filed: Aug. 8, 2025

(30) Foreign Application Priority Data
Apr. 8, 2025 (KR) 10-2025-0045102

(51) Int. Cl. H10P 74/00; G01R 31/26

(52) U.S. Cl. CPC H10P 74/273; G01R 31/2607

(57) ABSTRACT

A semiconductor device includes a substrate including active regions spaced apart from each other, and a test pattern arranged on the active regions. The test pattern includes test structures respectively located on the active regions, each test structure including a first insulating layer on the substrate, and a conductive layer on the first insulating layer, first test contacts, located on the test structures in a first region of the active regions, electrically connected to the conductive layer, and second test contacts located on a second region of the active regions. The second region is spaced apart from the first region. The second test contacts are electrically connected to the active regions. The test pattern further includes a first test wire electrically connected to the first test contacts, and a second test wire electrically connected to the second test contacts, and spaced apart from the first test wire.

### CROSS-REFERENCE TO RELATED APPLICATIONS

The present application claims priority under 35 U.S.C. 119(a) to Korean patent application number 10-2025-0045102 filed on Apr. 8, 2025, which is incorporated herein by reference in its entirety.

### BACKGROUND

### 1. Technical Field

Various embodiments relate to a semiconductor device and a method of monitoring process defects of the semiconductor device.

### 2. Related Art

Semiconductor devices are attracting attention as important components in the electronics industry due to desired characteristics such as miniaturization, multifunctionality, and/or low production costs. As the electronics industry advances, semiconductor devices are becoming increasingly highly integrated, and the difficulty of forming various wires and elements included in the semiconductor devices increases. For example, as distances between the various wires and elements included in the semiconductor devices decrease, even a slight misalignment between the wires and elements during a process of forming the semiconductor devices may cause defects in the semiconductor devices.

### SUMMARY

Objects of embodiments are not limited to the objects described herein, and other objects that are not described will be clearly understood by a person skilled in the art from the description below.

Various embodiments are directed to a semiconductor device capable of monitoring process defects caused by misalignment, and a method of monitoring process defects of the semiconductor device.

In an embodiment, a semiconductor device may include a substrate including a plurality of active regions spaced apart from each other, and a test pattern arranged on the plurality of active regions. The test pattern may include test structures respectively located on the plurality of active regions, each of the test structures including a first insulating layer on the substrate, and a conductive layer on the first insulating layer, first test contacts, located on the test structures in a first region of the plurality of active regions, electrically connected to the conductive layer, second test contacts located on a second region of the plurality of active regions, wherein the second region is spaced apart from the first region, and wherein the second test contacts are electrically connected to the plurality of active regions, a first test wire electrically connected to the first test contacts, and a second test wire electrically connected to the second test contacts, and spaced apart from the first test wire.

In an embodiment, a semiconductor device may include a substrate including a first active region and a second active region spaced apart from each other, and a test pattern arranged on the plurality of active regions. The test pattern may include test structures located on the first active region, each of the test structures including a first insulating layer on the substrate, and a conductive layer on the first insulating layer, first test contacts electrically connected to the conductive layer and located on the test structures, second test contacts located on the second active region, and electrically connected to the second active region, a first test wire electrically connected to the first test contacts, and a second test wire electrically connected to the second test contacts, and spaced apart from the first test wire.

In an embodiment, a method of monitoring process defects of a semiconductor device including a substrate including active regions including a first active region and a second active region, a conductive layer located on the substrate and electrically isolated from the active regions, a first test contact electrically connected to the conductive layer, and a second test contact electrically connected to at least one of the active regions may include applying a first voltage to a first test wire electrically connected to the first test contact, applying a second voltage to a second test wire electrically connected to the second test contact, and determining whether a process defect is present by measuring current flowing between the first test wire and the second test wire.

Various embodiments may provide a semiconductor device capable of monitoring process defects caused by misalignment, and a method of monitoring process defects of the semiconductor device.

Effects of various embodiments are not limited to those mentioned above, and other effects not explicitly described herein will be clearly understood by those skilled in the art from the scope of the claims.

### BRIEF DESCRIPTION OF THE DRAWINGS

The present disclosure will be more fully understood from the following detailed description and the accompanying drawings. The description and the drawings are provided for illustrative purposes only and are not intended to limit the scope of the present disclosure.

FIG. 1 is a diagram illustrating an example of a planar structure of a semiconductor device in accordance with an embodiment of the present disclosure.

FIG. 2 is an enlarged view of the test pattern of FIG. 1.

FIG. 3 is a diagram illustrating an example of a cross-sectional structure taken along line I-I′ of FIG. 2 in accordance with an embodiment of the present disclosure.

FIGS. 4 and 5 are diagrams illustrating examples of a cross-sectional structure taken along line II-II′ of FIG. 2 in accordance with an embodiment of the present disclosure.

FIGS. 6 and 7 are diagrams illustrating examples of a cross-sectional structure taken along line III-III′ of FIG. 2.

FIG. 8 is a diagram of another example of the test pattern 10 of FIG. 1 in accordance with an embodiment of the present disclosure.

FIG. 9 is a diagram illustrating an example of a cross-sectional structure taken along line IV-IV′ of FIG. 8 in accordance with an embodiment of the present disclosure.

FIG. 10 is a diagram illustrating an example of a cross-sectional structure taken along line V-V’ of FIG. 8.

FIGS. 11 and 12 are diagrams illustrating examples of a cross-sectional structure taken along line VI-VI′ of FIG. 8.

FIG. 13 is a diagram illustrating another example of the test pattern 10 of FIG. 1 in accordance with an embodiment of the present disclosure.

FIGS. 14 to 25 are diagrams illustrating examples of a method of manufacturing the semiconductor device according to embodiments of the present disclosure.

FIG. 26 is a flowchart illustrating a method of monitoring process defects of a semiconductor device according to embodiments of the present disclosure.

### DETAILED DESCRIPTION

Hereinafter, various embodiments will be described in detail with reference to the accompanying drawings. In the following description, like reference numerals may be used to designate the same components although the components are shown in different drawings. Furthermore, in the following description, a detailed description of known functions and configurations incorporated herein will be omitted when it may make the subject matter of the disclosure rather unclear. The terms such as “including,” “having,” and “comprising” used herein are generally intended to allow other components to be added unless the terms are used with the term “only”. Any references to singular may include plural unless expressly stated otherwise.

Also, in describing the components of the disclosure, there may be terms used like first, second, A, B, (a), and (b). These are solely for the purpose of differentiating one component from the other but not to imply or suggest the substances, order, sequence or number of the components.

In descriptions for the positional relationships of components, in the case where it is described that at least two components are “connected,” “coupled” or “linked,” it is to be understood that the at least two components may be directly “connected,” “coupled” or “linked” but may be indirectly “connected,” “coupled” or “linked” with another component interposed between the two components. Here, another component may be included in at least one of the at least two components which are “connected,” “couple” or “linked” with each other.

In descriptions for time flow relationships of components, an operating method or a fabricating method, in the case where pre and post relationships in terms of time or pre and post relationships in terms of flow are described, for example, by “after,” “following,” “next” or “before,” non-continuous cases may be included unless “immediately” or “directly” is used.

In the case where a numerical value for a component or its corresponding information (e.g., level, etc.) is mentioned, even though there is no separate explicit description, the numerical value or its corresponding information can be interpreted as including an error range that may be caused by various factors (for example, a process variable, an internal or external shock, noise, etc.).

Hereinafter, various embodiments will be described in detail with reference to accompanying drawings.

In the accompanying drawings, two directions on an upper surface of a substrate 200 are defined as a first direction FD and a second direction SD, respectively, and a direction protruding perpendicularly from the upper surface of the substrate 200 is defined as a third direction VD. The first direction FD and the second direction SD may be substantially perpendicular to each other. The third direction VD is substantially perpendicular to both the first direction FD and the second direction SD. In the following description, the terms “perpendicular” or “perpendicular direction” are used to mean substantially the same as the third direction VD. In the drawings, a direction indicated by an arrow and the opposite direction thereof represent the same direction.

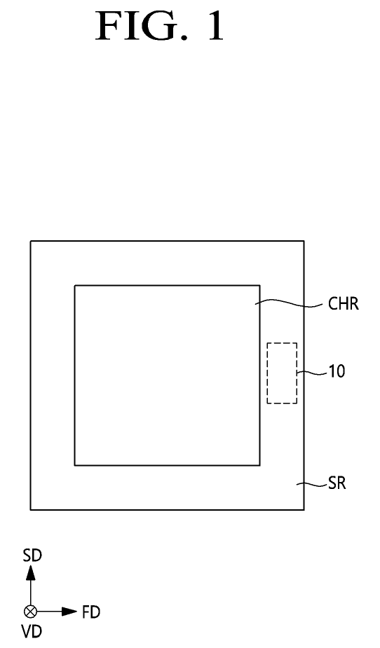

FIG. 1 is a diagram illustrating an example of a planar structure of a semiconductor device according to embodiments.

Referring to FIG. 1, the semiconductor device according to embodiments may include a chip region CHR and a scribe lane region SR. The chip region CHR may refer to a region in which circuits and elements constituting a single semiconductor device are located. The scribe lane region SR may refer to a region remaining around the chip region CHR after a separation process (for example, cutting or dicing) is performed. The scribe lane region SR may enclose the chip region CHR.

A test pattern 10 may be located in the scribe lane region SR. The test pattern 10 according to embodiments may be a pattern provided to monitor defects caused by misalignment of wires or contacts. In some embodiments, the test pattern 10 may be located in the chip region CHR.

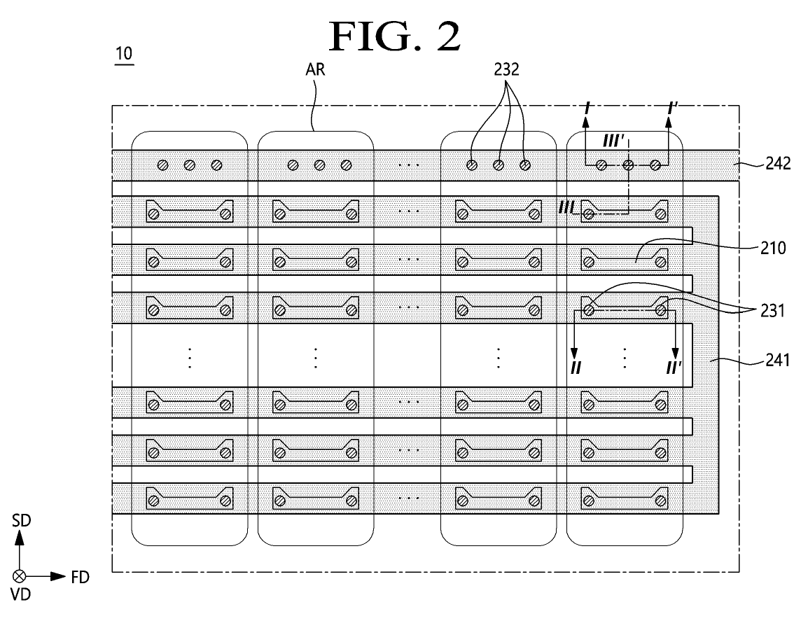

FIG. 2 is an enlarged view of the test pattern 10 of FIG. 1.

Referring to FIG. 2, the test pattern 10 may include at least one or more active regions AR. The active regions AR may be spaced apart from each other in the first direction FD. Each of the active regions AR may extend in the second direction SD. Test structures 210 may be located in the active region AR. The test structures 210 may be (for example, arranged to be) spaced apart from each other in the first direction FD and the second direction SD.

Second test contacts 232 may be located in a region (or section, area) of each of the active regions AR excluding a region where the test structures 210 are arranged (or disposed). Although the number of second test contacts 232 located in each active region AR is illustrated as three, the number is not limited thereto. The second test contacts 232 may be arranged to be spaced apart from each other in the first direction FD.

First test contacts 231 may be located to overlap the test structures 210 (or be disposed on, positioned within, or located on the test structures 210). In an embodiment, two of the first test contacts 231 are arranged to correspond to each test structure 210. The first test contacts 231 are spaced apart from each other in the first direction FD.

A first test wire 241 may extend in the first direction FD. A second test wire 242 may extend in the first direction FD. The second test wire 242 may be electrically isolated from the first test wire 241. The first test wire 241 may electrically connect the test structures 210.

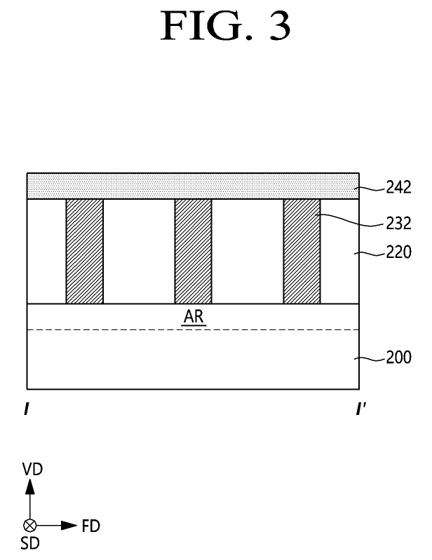

FIG. 3 is a diagram illustrating an example of a cross-sectional structure taken along line I–I′ of FIG. 2.

Referring to FIG. 3, a second insulating layer 220 may be located on the substrate 200. The second test contacts 232 may pass through the second insulating layer 220 and may be directly connected to the active regions AR of the substrate 200. Lower surfaces of the second test contacts 232 may contact an upper surface of the substrate 200. In an embodiment, the second test contacts 232 may extend into the substrate 200.

The second test wire 242 may be located on the second test contacts 232. The second test wire 242 may be electrically connected to all of the second test contacts 232. The second test wire 242 may extend in the first direction FD.

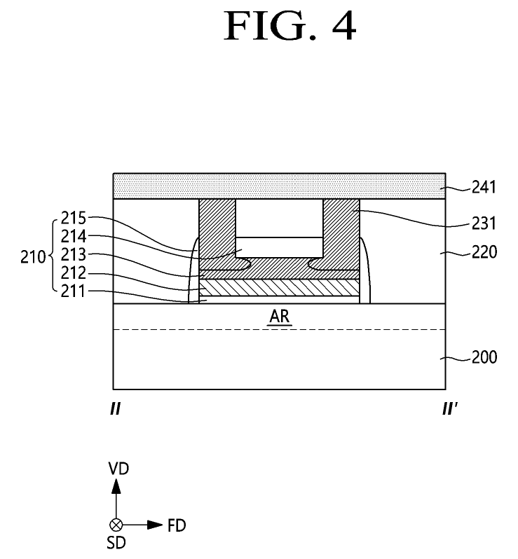

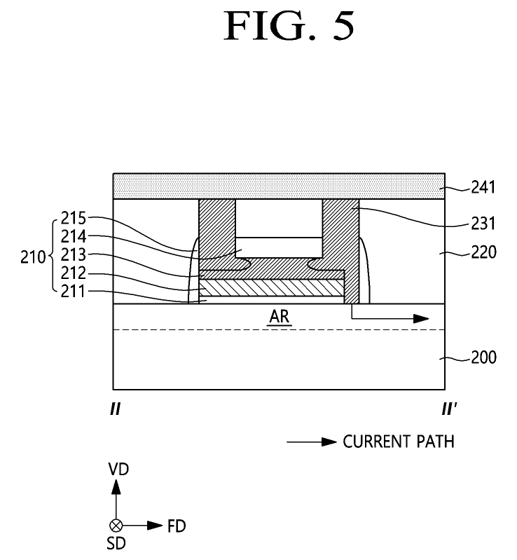

FIGS. 4 and 5 are diagrams illustrating examples of a cross-sectional structure taken along line II-II′ of FIG. 2.

Referring to FIG. 4, the test structure 210 may be located on the active region AR of the substrate 200. The test structure 210 may include a first insulating layer 211, a sub-conductive layer 212, a conductive layer 213, a capping layer 214, and a spacer 215. The first insulating layer 211 may contact the upper surface of the substrate 200 in the active region AR. The sub-conductive layer 212, the conductive layer 213, and the capping layer 214 may be sequentially stacked on the first insulating layer 211. In the first direction FD, widths of the first insulating layer 211, the sub-conductive layer 212, the conductive layer 213, and the capping layer 214 may be substantially the same. The spacer 215 may be located on side surfaces of the first insulating layer 211, the sub-conductive layer 212, the conductive layer 213, and the capping layer 214.

The second insulating layer 220 may cover the test structure 210. The first test contacts 231 may pass through the second insulating layer 220 and may be electrically connected to the test structure 210. The first test contacts 231 may be electrically connected to the conductive layer 213.

In an embodiment, lower surfaces of the first test contacts 231 may be spaced apart from an upper surface of the sub-conductive layer 212. In an embodiment, the lower surfaces of the first test contacts 231 may be spaced apart from the active region AR of the substrate 200. In an embodiment, the first test contacts 231 may be electrically isolated from the active region AR.

In an embodiment, two first test contacts 231 may be connected to the conductive layer 213. The first test contacts 231 are spaced apart from each other in the first direction FD. In an embodiment, a side surface of each of the first test contacts 231 is substantially flush with a corresponding side surface of the conductive layer 213. However, various embodiments are not limited thereto, and the side surface of each of the first test contacts 231 may be spaced apart from the corresponding side surface of the conductive layer 213 in the first direction FD. Upper surfaces of the first test contacts 231 may be substantially flush with an upper surface of the second insulating layer 220.

The first test wire 241 may be electrically connected to the first test contacts 231. In an embodiment, in an instance in which a voltage is applied to the first test wire 241, the applied voltage is transmitted to the conductive layer 213 through the two first test contacts 231 that are electrically connected to the conductive layer 213.

Referring to FIGS. 2 to 4, the test pattern 10 may be used to monitor process defects of the semiconductor device based on the amount of current flowing between the first test wire 241 and the second test wire 242.

In an embodiment, a positive voltage is applied to the first test wire 241, and a ground voltage is applied to the second test wire 242. As illustrated in FIG. 4, the first test contacts 231 may be electrically isolated from the active region AR of the substrate 200. Because the first test contacts 231 are electrically isolated from the active region AR, even if a positive voltage is applied to the first test wire 241, current may not flow through the active region AR. Because current does not flow through the active region AR, the first test contacts 231 and second test contacts 232 may be electrically isolated from each other. Accordingly, current may not flow even between the first test wire 241 and the second test wire 242. Alternatively, in contrast to the above, a ground voltage may be applied to the first test wire 241, and a positive voltage may be applied to the second test wire 242.

According to embodiments, in an instance in which no current flows between the first test wire 241 and the second test wire 242, the first test contacts 231 may be determined to be properly formed.

On the other hand, in an instance in which current flows between the first test wire 241 and the second test wire 242, the first test contacts 231 may be determined to be improperly formed.

Referring to FIG. 5, at least one of the first test contacts 231 that are electrically connected to the test structure 210 may penetrate the conductive layer 213, the sub-conductive layer 212, and the first insulating layer 211, and may be electrically connected to the active region AR of the substrate 200. In an embodiment, the first test wire 241 may be electrically connected to the active region AR through the at least one first test contact 231.

Referring to FIGS. 2, 3, and 5, in an embodiment, a positive voltage is applied to the first test wire 241, and a ground voltage is applied to the second test wire 242. As illustrated in FIG. 5, the first test contact 231 may be electrically connected to the active region AR of the substrate 200. Because the first test contact 231 and second test contacts 232 are located on the same active region AR, the first test contact 231 and the second test contacts 232 may be electrically connected through the active region AR. For example, current flows from the first test contact 231 to the second test contacts 232 along the active region AR. In an embodiment, a current path is formed in the active region AR. Accordingly, current may flow between the first test wire 241 and the second test wire 242. Alternatively, in contrast to the above, a ground voltage may be applied to the first test wire 241, and a positive voltage may be applied to the second test wire 242. In this case, current may flow from the second test contacts 232 to the first test contact 231 along the active region AR.

According to embodiments, in an instance in which current flows between the first test wire 241 and the second test wire 242, it may be determined that a punch (or deformation) -has occurred at a location where the first test contacts 231 are formed. In other words, the first test contacts 231 may be determined to be improperly formed.

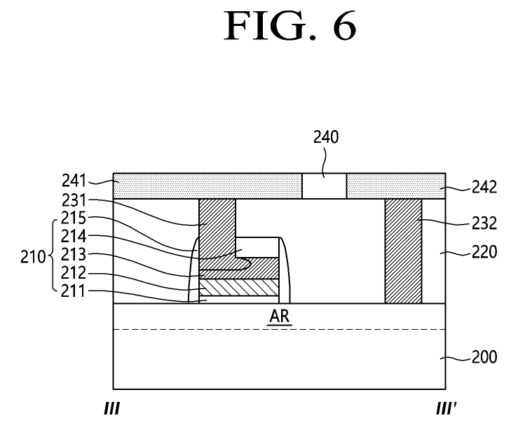

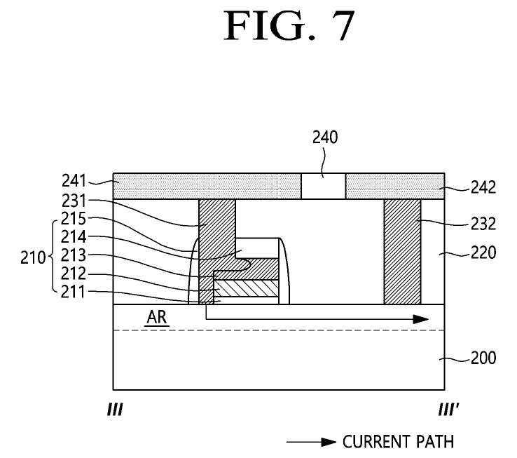

FIGS. 6 and 7 are diagrams illustrating examples of a cross-sectional structure taken along line III-III′ of FIG. 2.

Referring to FIG. 6, the first test wire 241 may be electrically connected to the test structure 210 through the first test contacts 231. In an embodiment, the first test contacts 231 are electrically isolated from the active region AR. The lower surfaces of the first test contacts 231 may be spaced apart from the upper surface of the sub-conductive layer 212.

The second test wire 242 may be spaced apart from the first test wire 241. The second test wire 242 may be electrically isolated from the first test wire 241. The second test wire 242 may be electrically connected to the active region AR through the second test contacts 232.

In an embodiment, a positive voltage may be applied to the first test wire 241, and a ground voltage may be applied to the second test wire 242. As shown in FIG. 6, the first test contacts 231 may be electrically isolated from the active region AR. Because the first test contacts 231 are electrically isolated from the active region AR, even if a positive voltage is applied to the first test wire 241, current may not flow through the active region AR. Because current does not flow through the active region AR, the first test contacts 231 and the second test contacts 232 may be electrically isolated from each other. Accordingly, current may not flow even between the first test wire 241 and the second test wire 242. Therefore, the first test contacts 231 may be determined to be properly formed.

Referring to FIG. 7, at least one of the first test contacts 231 that are electrically connected to the test structure 210 may penetrate the conductive layer 213, the sub-conductive layer 212, and the first insulating layer 211, and may be electrically connected to the active region AR of the substrate 200. In an embodiment, the first test wire 241 may be connected to the active region AR through the at least one first test contact 231.

Referring to FIGS. 2, 3, and 7, in an embodiment, a positive voltage is applied to the first test wire 241, and a ground voltage is applied to the second test wire 242. As illustrated in FIG. 7, the first test contact 231 may be electrically connected to the active region AR of the substrate 200. Because the first test contact 231 and second test contacts 232 are located on the same active region AR, the first test contact 231 and the second test contacts 232 may be electrically connected through the active region AR. For example, current flows from the first test contact 231 to the second test contacts 232 along the active region AR. In an embodiment, a current path may be formed in the active region AR. Accordingly, current may flow between the first test wire 241 and the second test wire 242.

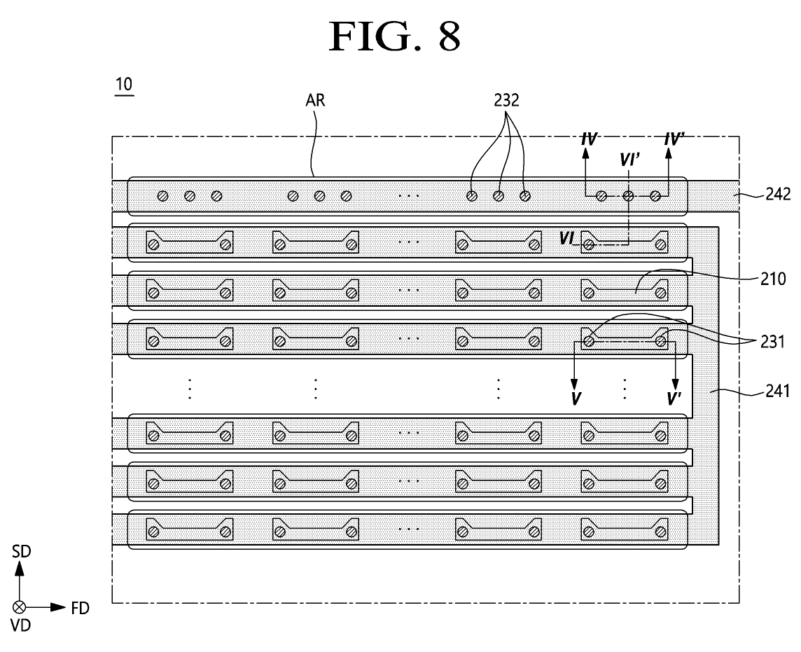

FIG. 8 is a diagram of another example of the test pattern 10 of FIG. 1.

Referring to FIG. 8, the test pattern 10 may include at least one or more active regions AR. The active regions AR may be spaced apart from each other in the second direction SD. The active regions AR may extend in the first direction FD. Test structures 210 may be located in the active regions AR. The test structures 210 may be arranged to be spaced apart from each other in the first direction FD and the second direction SD.

The second test contacts 232 may be located in a region of the active regions AR excluding regions where the test structures 210 are arranged. The second test contacts 232 may be (for example, disposed, located, arranged to be) spaced apart from each other in the first direction FD

The first test contacts 231 may be located to overlap the test structures 210. In an embodiment, two of the first test contacts 231 may be arranged to correspond to each test structure 210. The first test contacts 231 may be spaced apart from each other in the first direction FD.

The first test wire 241 may extend in the first direction FD. The second test wire 242 may extend in the first direction FD. The second test wire 242 may be electrically isolated from the first test wire 241. The first test wire 241 may electrically connect the test structures 210. In an embodiment, each portion of the first test wire 241 that extends in the first direction FD may overlap a corresponding one of the active regions AR.

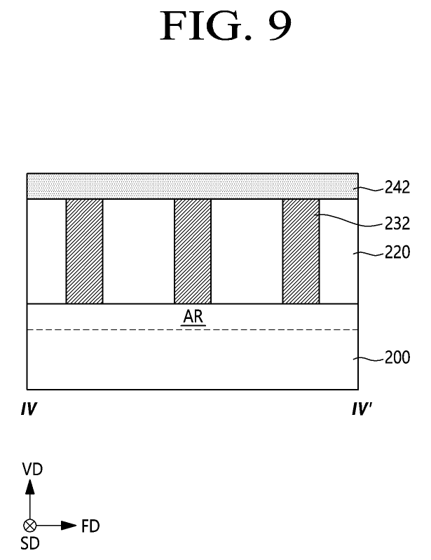

FIG. 9 is a diagram illustrating an example of a cross-sectional structure taken along line IV-IV′ of FIG. 8.

Referring to FIG. 9, the second test contacts 232 may penetrate the second insulating layer 220, and may be directly connected to the active region AR of the substrate 200. The lower surfaces of the second test contacts 232 may contact the upper surface of the substrate 200. In an embodiment, the second test contacts 232 extend into the substrate 200.

The second test wire 242 may be located on the second test contacts 232. The second test wire 242 may be electrically connected to all of the second test contacts 232. The second test wire 242 may extend in the first direction FD. Referring to FIGS. 8 and 9, the second test contacts 232 may be electrically connected to each other through a single active region AR.

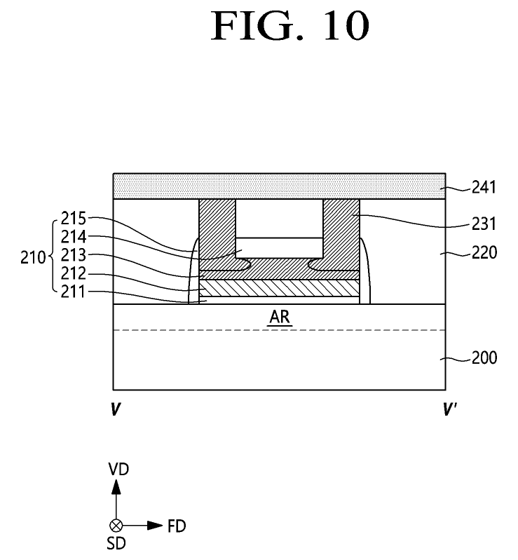

FIG. 10 illustrates an example of a cross-sectional structure taken along line V–V′ of FIG. 8.

Referring to FIG. 10, the first test contacts 231 may penetrate the second insulating layer 220, and may be electrically connected to the test structure 210. The first test contacts 231 may be electrically connected to the conductive layer 213.

In an embodiment, the lower surfaces of the first test contacts 231 may be spaced apart from the upper surface of the sub-conductive layer 212. In an embodiment, the lower surfaces of the first test contacts 231 may be spaced apart from the active region AR of the substrate 200. In an embodiment, the first test contacts 231 may be electrically isolated from the active region AR.

In an embodiment, a side surface of each of the first test contacts 231 may be (disposed) substantially flush with a corresponding side surface of the sub-conductive layer 212. However, various embodiments are not limited thereto, and the side surface of each of the first test contacts 231 may be spaced apart from the corresponding side surface of the sub-conductive layer 212 in the first direction FD. The upper surfaces of the first test contacts 231 may be substantially flush with the upper surface of the second insulating layer 220.

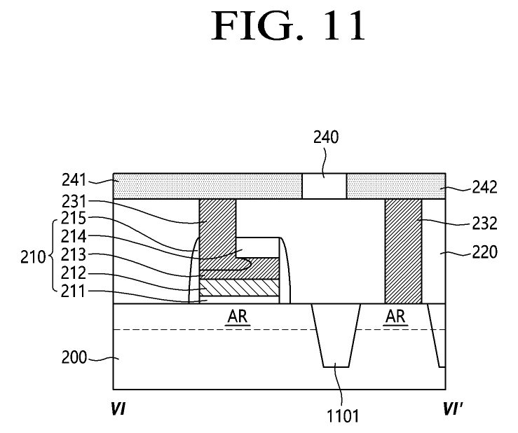

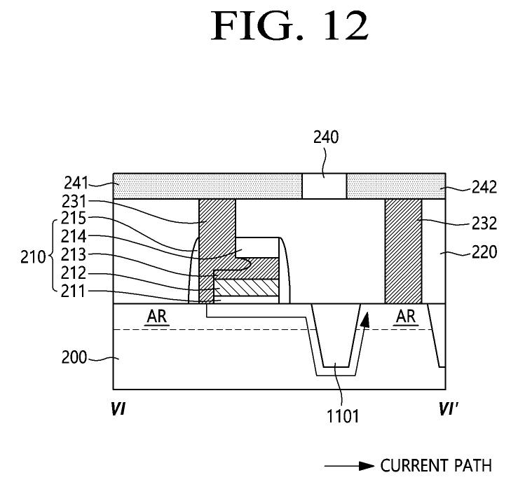

FIGS. 11 and 12 illustrate examples of cross-sectional structures taken along line VI–VI′ of FIG. 8.

Referring to FIG. 11, at least one element isolation layer 1101 may be located in the substrate 200. The element isolation layer 1101 may divide the active region AR into parts (i.e., sections, areas). The element isolation layer 1101 may be formed by using a trench-type element isolation technique such as shallow trench isolation (STI). The element isolation layer 1101 may include at least two elements selected from a group consisting of silicon (Si), oxygen (O), nitrogen (N), carbon (C), and hydron (H). The element isolation layer 1101 may include silicon oxide, silicon nitride, silicon oxynitride, a low-k dielectric, a high-k dielectric, or a combination thereof.

The first test wire 241 may be electrically connected to the test structure 210 through the first test contacts 231. In an embodiment, the first test contacts 231 may be electrically isolated from the active region AR. The lower surfaces of the first test contacts 231 may be spaced apart from the upper surface of the sub-conductive layer 212.

The second test wire 242 may be spaced apart from the first test wire 241. The second test wire 242 may be electrically isolated from the first test wire 241. The second test wire 242 may be electrically connected to the active region AR through the second test contacts 232.

In an embodiment, a positive voltage is applied to the first test wire 241, and a ground voltage is applied to the second test wire 242. As illustrated in FIG. 11, the first test contacts 231 may be electrically isolated from the active region AR. Because the first test contacts 231 are electrically isolated from the active region AR, even if a positive voltage is applied to the first test wire 241, current may not flow through the active region AR. Because current does not flow through the active region AR, the first test contacts 231 and the second test contacts 232 may be electrically isolated from each other. Accordingly, current may not flow even between the first test wire 241 and the second test wire 242. Therefore, the first test contacts 231 may be determined to be properly formed.

Referring to FIG. 12, at least one of the first test contacts 231 connected to the test structure 210 may penetrate the conductive layer 213, the sub-conductive layer 212, and the first insulating layer 211, and may be electrically connected to the active region AR of the substrate 200. In an embodiment, the first test wire 241 may be electrically connected to the active region AR through the at least one first test contact 231.

Referring to FIGS. 8, 9, and 12, in an embodiment, a positive voltage is applied to the first test wire 241, and a ground voltage is applied to the second test wire 242. As illustrated in FIG. 12, the first test contact 231 may be electrically connected to the active region AR of the substrate 200.

The first test contact 231 and the second test contacts 232 may be located on different active regions AR. The active region AR connected to the first test contact 231 may be separated from the active region AR connected to the second test contacts 232. Even when the active regions AR are separated, the first test contact 231 and the second test contacts 232 may be electrically connected. For example, current flows (along current path CURRENT PATH) from the first test contact 231 to the second test contacts 232 along the active region AR and a boundary between the element isolation layer 1101 and the substrate 200.

In embodiments, in an instance in which current flows between the first test wire 241 and the second test wire 242, it may be determined that a punch has occurred at a location where the first test contacts 231 are formed. In other words, the first test contacts 231 may be determined to be improperly formed.

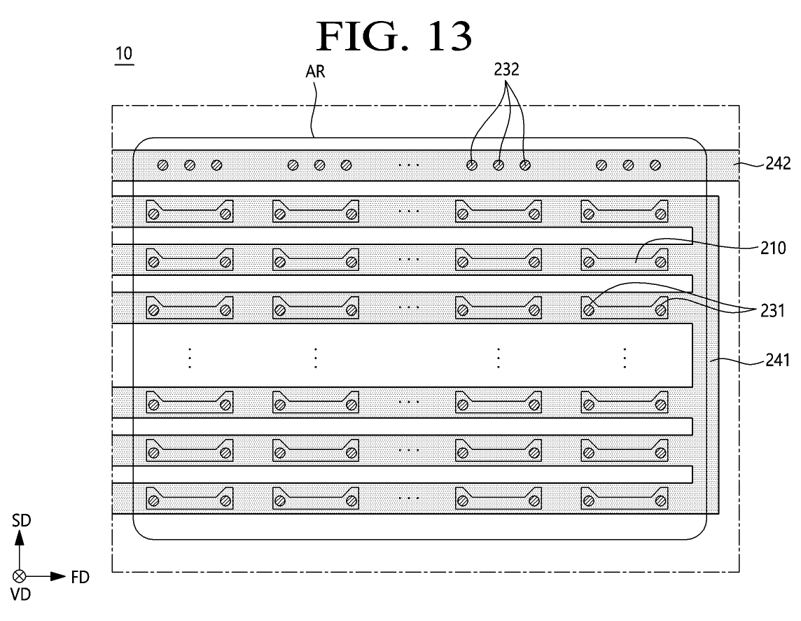

FIG. 13 illustrates another example of the test pattern 10 of FIG. 1.

Referring to FIG. 13, the test pattern 10 may include a single active region AR. The active region AR may extend in the first direction FD and the second direction SD. Test structures 210 may be located in the active region AR. The test structures 210 may be spaced apart from each other in the first direction FD and the second direction SD. Second test contacts 232 may be located in a region of the active region AR excluding a region in which the test structures 210 are located. The second test contacts 232 may be spaced apart from each other in the first direction FD.

The first test contacts 231 may be located to overlap the test structures 210. In an embodiment, two of the first test contacts 231 are located to correspond to one test structure 210. The first test contacts 231 may be spaced apart from each other in the first direction FD.

The first test wire 241 may extend in the first direction FD. The second test wire 242 may extend in the first direction FD. The second test wire 242 may be electrically isolated from the first test wire 241. The first test wire 241 may electrically connect the test structures 210. In an embodiment, the first test wire 241 and the second test wire 242 may overlap the single common active region AR.

The first test contacts 231, the second test contacts 232, the test structure 210, the first test wire 241, and the second test wire 242 may be substantially the same as the first test contacts 231, the second test contacts 232, the test structure 210, the first test wire 241, and the second test wire 242 described with reference to FIGS. 1 to 12.

In an embodiment, a positive voltage may be applied to the first test wire 241, and a ground voltage may be applied to the second test wire 242. After the voltages are applied, in an instance in which no current flows between the first test wire 241 and the second test wire 242, the first test contacts 231 may be determined to be properly formed. On the other hand, in the case in which current flows between the first test wire 241 and the second test wire 242, the first test contacts 231 may be determined to be improperly formed.

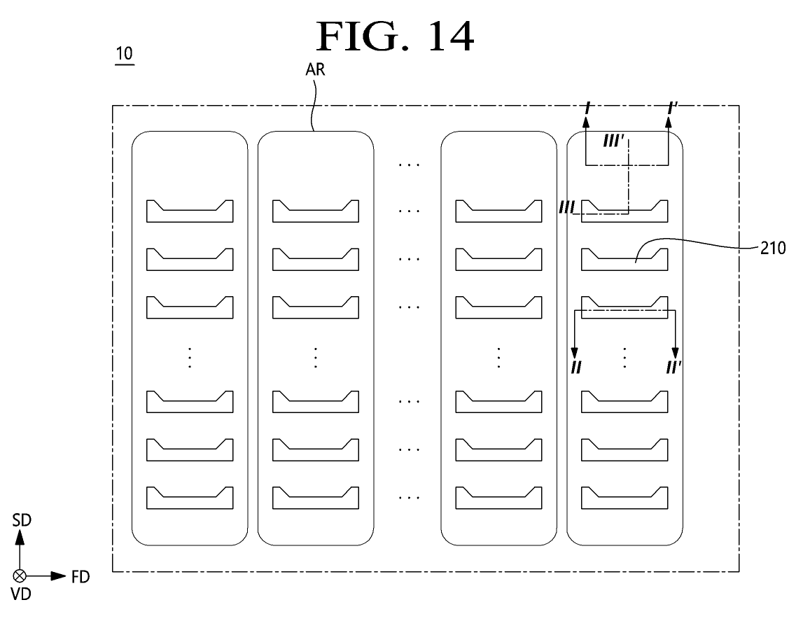

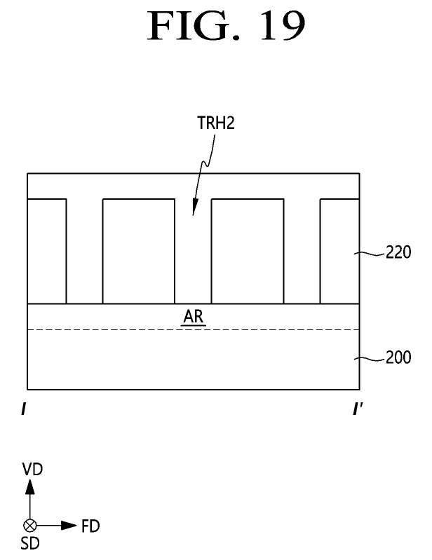

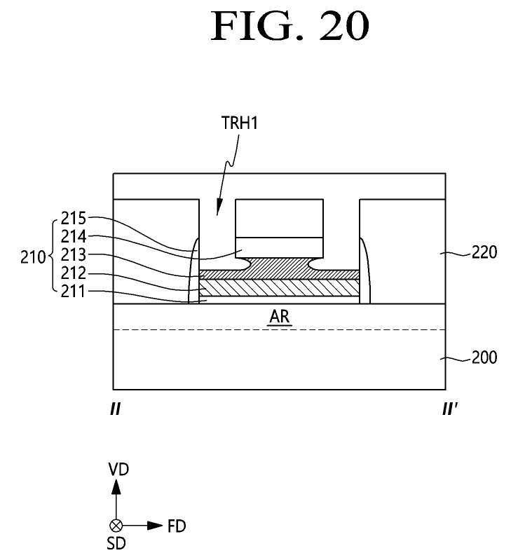

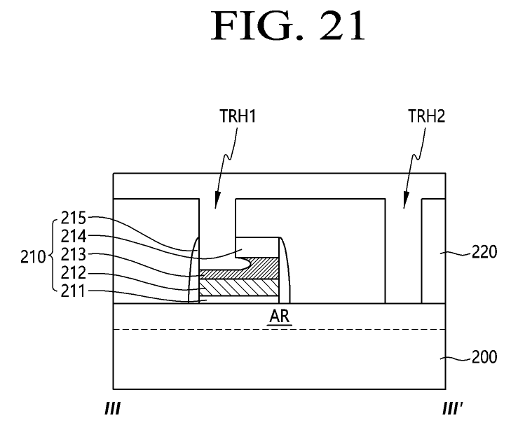

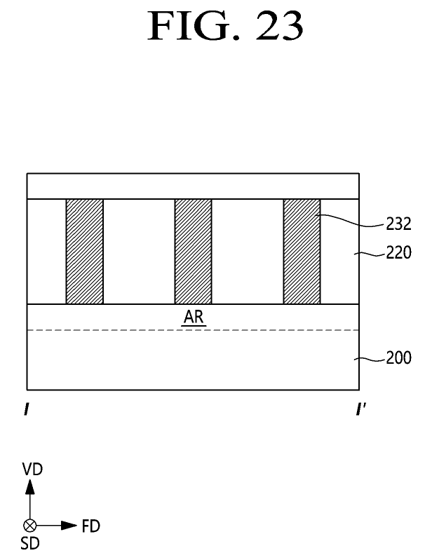

FIGS. 14 to 25 are diagrams illustrating an example of a method of manufacturing the semiconductor device according to embodiments.

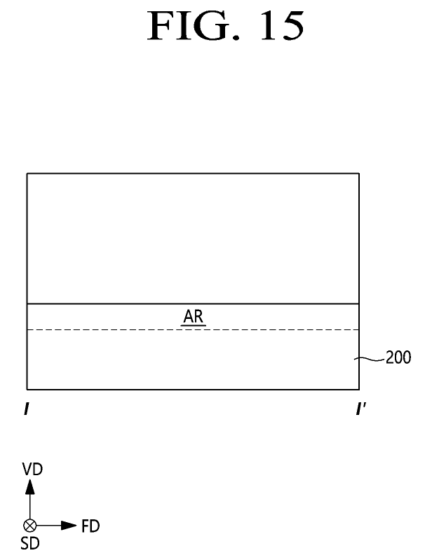

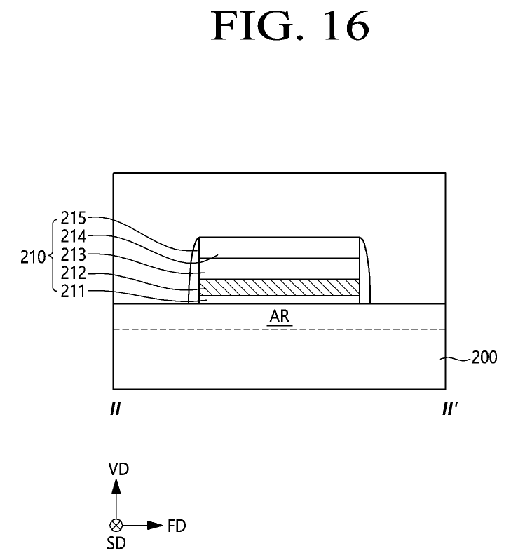

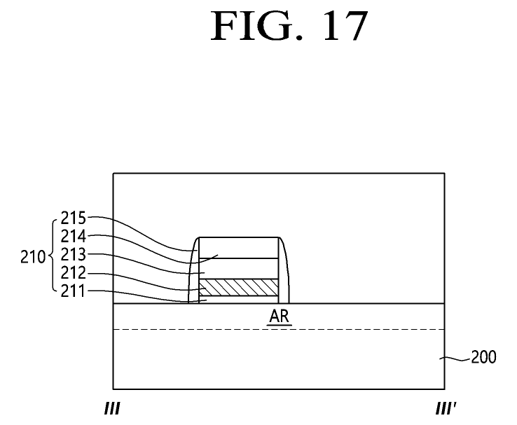

Referring to FIGS. 14 to 17, the active regions AR may be formed in the substrates 200. FIG. 14 illustrates a planar structure of the semiconductor device 10. FIG. 15 illustrates a cross-sectional view along the line I-I’ of FIG. 14. FIG. 16 illustrates a cross-sectional view along the line II-II’ of FIG. 14. FIG. 17 illustrates a cross-sectional view along the line III-III’ of FIG. 14.

As described with respect to FIGS. 14 to 17 herein, the substrate 200 may include a semiconductor substrate 200 such as a silicon wafer or a silicon-on-insulator (SOI) wafer. The substrate 110 may include a group III-V semiconductor substrate, for example, a substrate formed of a compound semiconductor such as GaAs. The substrate 200 may include single-crystalline silicon, polysilicon, amorphous silicon, single-crystalline silicon-germanium, polycrystalline silicon-germanium, carbon-doped silicon, or a combination thereof.

In an embodiment, the active region AR includes single-crystal silicon having P-type or N-type impurities. The P-type impurities may include boron (B), boron monofluoride (BF), boron difluoride (BF₂), or a combination thereof. The N-type impurities may include phosphorous (P), arsenic (As), or a combination thereof.

The test structures 210 may be formed on the active region AR of the substrate 200. First, the first insulating layer 211, the sub-conductive layer 212, the conductive layer 213, and the capping layer 214 may be sequentially formed on the substrate 200. Thereafter, the first insulating layer 211, the sub-conductive layer 212, the conductive layer 213, and the capping layer 214 may be etched. Subsequently, the spacer 215 may be formed on the side surfaces of the first insulating layer 211, the sub-conductive layer 212, the conductive layer 213, and the capping layer 214.

The first insulating layer 211, the capping layer 214, and the spacer 215 may include silicon oxide, silicon nitride, silicon oxynitride, a low-k dielectric, a high-k dielectric, or a combination thereof. The sub-conductive layer 212 and the conductive layer 213 may include a conductive material such as metal, metal oxide, metal nitride, metal silicide, polysilicon, conductive carbon, or a combination thereof.

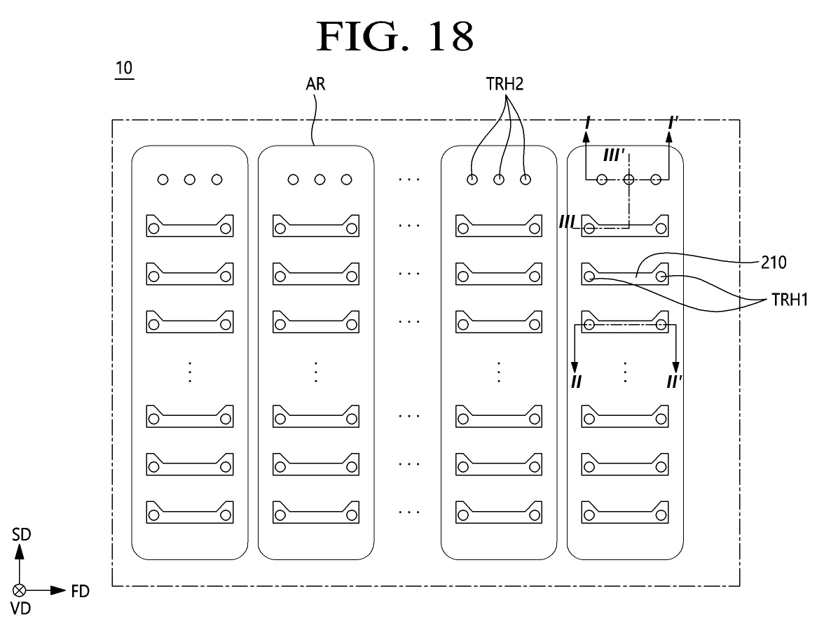

Referring to FIGS. 18 to 21, the second insulating layer 220 may be formed on the substrate 200 and the test structures 210. The second insulating layer 220 may include silicon oxide, silicon nitride, silicon oxynitride, a low-k dielectric, a high-k dielectric, or a combination thereof.

A first through hole TRH1 and a second through hole TRH2 may be formed through the second insulating layer 220. A process of forming the first through hole TRH1 and the second through hole TRH2 may include an etching process. The first through hole TRH1 may pass through the second insulating layer 220 and the capping layer 214 to expose the conductive layer 213. The second through hole TRH2 may pass through the second insulating layer 220 to expose the active region AR of the substrate 200.

The first through hole TRH1 may be formed to overlap the test structure 210. In an embodiment, two first through holes TRH1 are formed on the test structure 210. The second through hole TRH2 may be formed to be spaced apart from the first through holes TRH1. The second through hole TRH2 may be formed in a region other than the region where the test structures 210 are located.

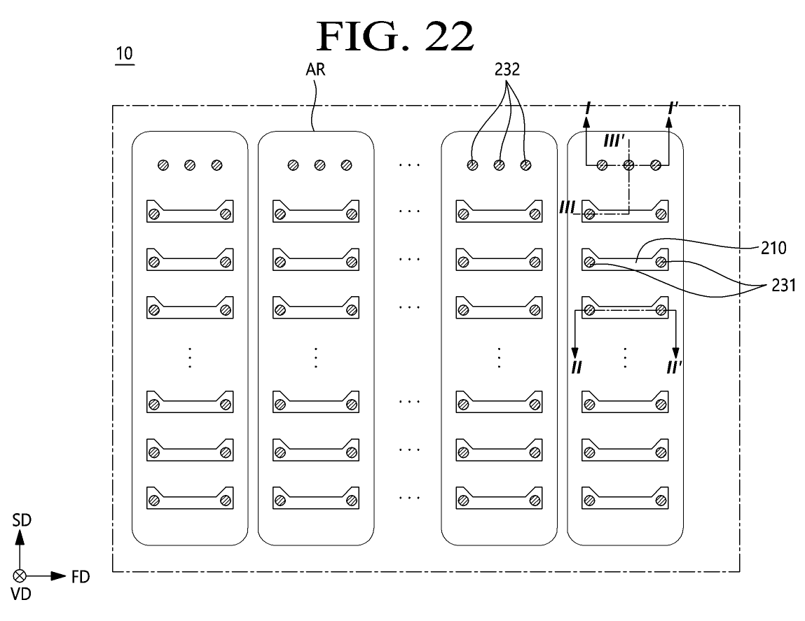

Referring to FIGS. 22 to 25, the first through hole TRH1 and the second through hole TRH2 may be filled with conductive material. As the first through hole TRH1 and the second through hole TRH2 are filled with the conductive material, the first test contacts 231 and the second test contacts 232 may be formed, respectively.

The upper surfaces of the first test contacts 231 and the upper surfaces of the second test contacts 232 may be substantially flush with each other.

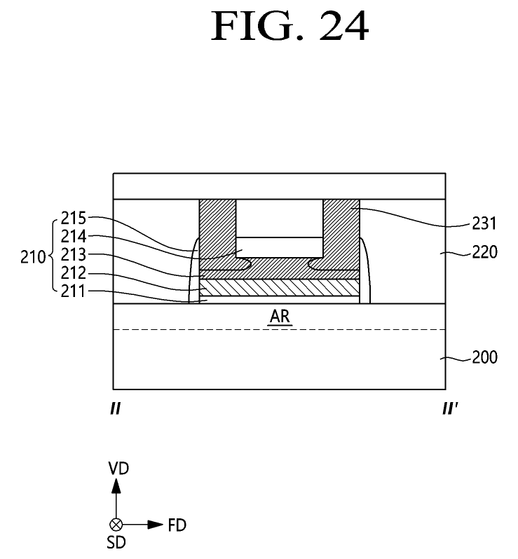

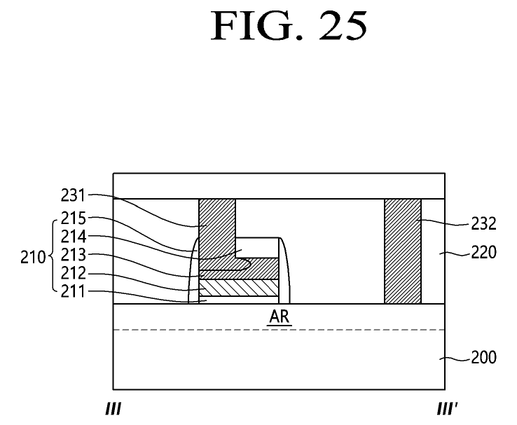

As illustrated in FIGS. 24 and 25, in an instance in which the first test contacts 231 are properly formed, the first test contacts 231 and the second test contacts 232 may be electrically isolated from each other. However, in an instance in which the first test contacts 231 are not properly formed, that is, in the case where at least one of the first test contacts 231 penetrates the conductive layer 213, the sub-conductive layer 212, and the first insulating layer 211 to contact the active region AR, the first test contact 231 and the second test contacts 232 may be electrically connected through the active region AR.

Referring again to FIGS. 2, 3, 4, and 6, the second insulating layer 220 may be formed on the first test contacts 231. The first test wire 241 may be formed to penetrate the second insulating layer 220. The first test wire 241 may be connected to the first test contacts 231. The second test wire 242 may be connected to the second test contacts 232. The first test wire 241 and the second test wire 242 may be spaced apart from each other.

In an instance in which the first test contacts 231 are properly formed, the first test wire 241 and the second test wire 242 may be electrically isolated from each other. In the case where the first test contacts 231 are improperly formed, the first test wire 241 and the second test wire 242 may be electrically connected.

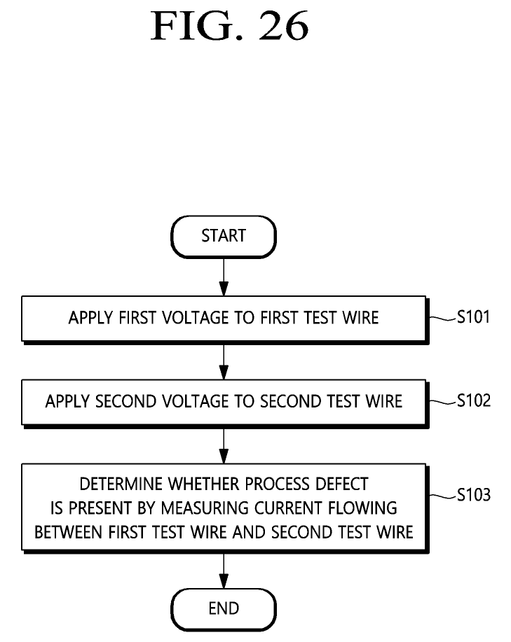

FIG. 26 is a flowchart illustrating a method of monitoring process defects of the semiconductor device according to embodiments.

Referring to FIG. 26, the method of monitoring process defects of the semiconductor device according to embodiments may include an operation S101 of applying a first voltage to the first test wire 241, an operation S102 of applying a second voltage to the second test wire 242, and an operation S103 of determining whether a process defect has occurred by measuring the amount of current flowing between the first test wire 241 and the second test wire 242.

The semiconductor device described with reference to FIG. 26 may include the substrate 200 including the active region AR, a gate electrode located on the substrate 200 and electrically isolated from the active region AR, the first test contacts 231 connected to the gate electrode, and the second test contacts 232 directly connected to the active region AR.

The first test wire 241 may be connected to one side of the first test contacts 231. The second test wire 242 may be connected to one side of the second test contacts 232. The first test contacts 231 may electrically connect the sub-conductive layer 212 and the first test wire 241. The second test contacts 232 may electrically connect the active region AR and the second test wire 242.

In the operation S101 of applying the first voltage to the first test wire 241, the first voltage may be a positive voltage. In the operation S102 of applying the second voltage to the second test wire 242, the second voltage may be a ground voltage. Alternatively, the first voltage may be a ground voltage, and the second voltage may be a positive voltage.

In the operation S103 of determining whether a process defect has occurred by measuring the amount of current flowing between the first test wire 241 and the second test wire 242, in an instance in which no current flows between the first test wire 241 and the second test wire 242, it may be determined that no process defect has occurred. In an instance in which current flows between the first test wire 241 and the second test wire 242, it may be determined that a process defect has occurred.

According to embodiments, the test pattern 10 may be provided that enables measurement of current flowing between the first test contacts 231 and the second test contacts 232 depending on whether a punch (or gap, deformation, discontinuity, etc.) is present in the first test contacts 231. In an instance in which no current flows between the first test wire 241 and the second test wire 242, the first test contacts 231 may be determined to be properly formed on the test structure 210. In an instance in which current flows between the first test wire 241 and the second test wire 242, the first test contacts 231 may be determined to be improperly formed on the test structure 210. In particular, it may be determined that a punch phenomenon has occurred during the formation of the first test contacts 231. Therefore, according to embodiments, process defects caused by misalignment may be effectively monitored.

The above description is merely illustrative of the technical spirit of the present disclosure, and various modifications and changes may be made thereto by those skilled in the art without departing from the essential characteristics of the present disclosure. Furthermore, various embodiments are not intended to limit the technical spirit of the present disclosure but to illustrate the technical spirit of the present disclosure, and the technical spirit of the present disclosure is not limited by these embodiments.

What is claimed is:

1. A semiconductor device comprising:
a substrate including a plurality of active regions spaced apart from each other; and
a test pattern arranged on the plurality of active regions,
wherein the test pattern comprises:
test structures respectively located on the plurality of active regions, each of the test structures including a first insulating layer on the substrate, and a conductive layer on the first insulating layer;
first test contacts, located on the test structures in a first region of the plurality of active regions, electrically connected to the conductive layer;
second test contacts located on a second region of the plurality of active regions, wherein the second region is spaced apart from the first region, and wherein the second test contacts are electrically connected to the plurality of active regions;
a first test wire electrically connected to the first test contacts; and
a second test wire electrically connected to the second test contacts, and spaced apart from the first test wire.

2. The semiconductor device according to claim 1, wherein the first test wire and the second test wire are located in an identical layer.

3. The semiconductor device according to claim 1, wherein the first test contacts are electrically isolated from the plurality of active regions.

4. The semiconductor device according to claim 3, wherein the first test contacts are spaced apart from the first insulating layer.

5. The semiconductor device according to claim 1, wherein at least one of the first test contacts is electrically connected to one of the plurality of active regions.

6. The semiconductor device according to claim 5, wherein at least one of the first test contacts penetrates the first insulating layer.

7. The semiconductor device according to claim 1, wherein either the first test wire or the second test wire is configured to receive an applied ground voltage.

8. A semiconductor device comprising:
a substrate including a first active region and a second active region spaced apart from each other; and
a test pattern arranged on the first active region and the second active region,
wherein the test pattern comprises:
test structures located on the first active region, each of the test structures including a first insulating layer on the substrate, and a conductive layer on the first insulating layer;
first test contacts electrically connected to the conductive layer and located on the test structures;
second test contacts located on the second active region, and electrically connected to the second active region;
a first test wire electrically connected to the first test contacts; and
a second test wire electrically connected to the second test contacts, and spaced apart from the first test wire.

9. The semiconductor device according to claim 8, wherein the test structures are not located on the second active region.

10. The semiconductor device according to claim 8, wherein the second test contacts are not located on the first active region.

11. The semiconductor device according to claim 8, wherein the first test contacts are electrically isolated from the first active region.

12. The semiconductor device according to claim 11, wherein the first test contacts are spaced apart from the first insulating layer.

13. The semiconductor device according to claim 8, wherein at least one of the first test contacts is electrically connected to the first active region.

14. The semiconductor device according to claim 13, wherein the at least one of the first test contacts penetrates the first insulating layer.

15. The semiconductor device according to claim 8, wherein either the first test wire or the second test wire is configured to receive an applied ground voltage.

16. A method of monitoring process defects of a semiconductor device comprising a substrate including active regions including a first active region and a second active region, a conductive layer located on the substrate and electrically isolated from the active regions, a first test contact electrically connected to the conductive layer, and a second test contact electrically connected to at least one of the active regions, the method comprising:
applying a first voltage to a first test wire electrically connected to the first test contact;
applying a second voltage to a second test wire electrically connected to the second test contact; and
determining whether a process defect is present by measuring current flowing between the first test wire and the second test wire.

17. The method according to claim 16, wherein the determining of whether a process defect is present comprises determining that a process defect is present in an instance in which current flows between the first test wire and the second test wire, and determining that no process defect is present in an instance in which no current flows between the first test wire and the second test wire.

18. The method according to claim 16, wherein either of the first voltage or the second voltage includes a ground voltage.

19. The method according to claim 16, wherein the first test contact and the second test contact are both located on the first active region or the second active region.

20. The method according to claim 16, wherein the first test contact is located on the first active region and the second test contact is located on the second active region.
